(19) United States
(12) Patent Application Publication
(10) Pub. No.: US 2026/0269823 A1
(43) Pub. Date: Sep. 10, 2026

(54) DC-DC CONVERTER AND CONTROL METHOD

(71) Applicant: Panasonic Intellectual Property Management Co., Ltd., Osaka (JP)

(72) Inventors: Hiromu MATSUMOTO, Gifu (JP); Hiroyuki HOSOI, Osaka (JP)

(21) Appl. No.: 19/165,833

(22) PCT Filed: Jun. 7, 2024
(86) PCT No.: PCT/JP2024/020821

§ 371 Date: Sep. 16, 2025

(30) Foreign Application Priority Data
Jul. 7, 2023 (JP) 2023-112610

(51) Int. Cl. H03K 17/14; H02M 1/00; H02M 1/088; H02M 3/335; H03K 7/08

(52) U.S. Cl. CPC H03K 17/145; H02M 1/0054; H02M 1/088; H02M 3/33573; H03K 7/08

(57) ABSTRACT

A DC-DC converter includes: a control circuit that controls switching of a first switch, a second switch, a third switch, and a fourth switch to cause an effective value of a current flowing through at least one switch among the first switch, the second switch, the third switch, and the fourth switch to be larger than an effective value of a current flowing through any of switches other than the at least one switch. On-resistance of the at least one switch is lower than that of any of the switches other than the at least one switch, cooling performance of a cooling structure of the at least one switch is higher than that of any of the switches other than the at least one switch, or heat resistance of the at least one switch is higher than that of any of the switches other than the at least one switch.

### TECHNICAL FIELD

The present disclosure relates to a DC-DC converter of an isolated type and others.

### BACKGROUND ART

Patent Literature (PTL) 1 discloses a device that includes a transformer of an isolated type, a primary-side alternating current (AC) voltage application means (full-bridge circuit), a secondary-side rectification means, an output smoothing capacitor, and an inductor provided at the input or the output of the transformer. This device is capable of adjusting the output voltage by performing phase-shift control of switches included in the primary-side full-bridge circuit.

### CITATION LIST

### Patent Literature

[PTL 1] Japanese Unexamined Patent Application Publication No. 2013-192436

### SUMMARY OF INVENTION

### Technical Problem

In the device disclosed in PTL 1, however, the effective values of currents flowing through the switches on the primary side are uniform when phase-shift control is performed. For this reason, to achieve compliance with operating conditions that require a large output current when an output voltage is low, it is necessary to pass a large current through the switches on the primary side. To reduce conduction loss, heat generation, etc. in the switches, all switches on the primary side need to be switches with low on-resistance, switches having a cooling structure with high cooling performance, or switches with high heat resistance. This results in cost increase.

In view of this, the present disclosure provides a DC-DC converter and others capable of achieving compliance with the operating conditions that require a large output current when an output voltage is low, while reducing costs.

### Solution to Problem

A DC-DC converter according to the present disclosure is a DC-DC converter of an isolated type, the DC-DC converter including: a first switch that is provided on a first path connecting an input terminal and a ground terminal; a second switch that is provided on the first path and connected in series with the first switch; a third switch that is provided on a second path connecting the input terminal and the ground terminal, the second path being different from the first path; a fourth switch that is provided on the second path and connected in series with the third switch; a transformer that includes a primary winding connected between a first node and a second node, the first node being located between the first switch and the second switch on the first path, the second node being located between the third switch and the fourth switch on the second path; a rectifier circuit that is connected to a secondary winding of the transformer; and a control circuit that controls switching of the first switch, the second switch, the third switch, and the fourth switch to cause an effective value of a current flowing through at least one switch among switches to be larger than an effective value of a current flowing through any of the switches other than the at least one switch, the switches being the first switch, the second switch, the third switch, and the fourth switch, wherein one of the following is satisfied: on-resistance of the at least one switch is lower than on-resistance of any of the switches other than the at least one switch; cooling performance of a cooling structure of the at least one switch is higher than cooling performance of a cooling structure of any of the switches other than the at least one switch; or heat resistance of the at least one switch is higher than heat resistance of any of the switches other than the at least one switch.

A control method according to the present disclosure is a control method executed by a DC-DC converter of an isolated type, including: a first switch that is provided on a first path connecting an input terminal and a ground terminal; a second switch that is provided on the first path and connected in series with the first switch; a third switch that is provided on a second path connecting the input terminal and the ground terminal, the second path being different from the first path; a fourth switch that is provided on the second path and connected in series with the third switch; a transformer that includes a primary winding connected between a first node and a second node, the first node being located between the first switch and the second switch on the first path, the second node being located between the third switch and the fourth switch on the second path; and a rectifier circuit that is connected to a secondary winding of the transformer, the control method including: controlling switching of the first switch, the second switch, the third switch, and the fourth switch to cause an effective value of a current flowing through at least one switch among switches to be larger than an effective value of a current flowing through any of the switches other than the at least one switch, the switches being the first switch, the second switch, the third switch, and the fourth switch, wherein one of the following is satisfied: on-resistance of the at least one switch is lower than on-resistance of any of the switches other than the at least one switch; cooling performance of a cooling structure of the at least one switch is higher than cooling performance of a cooling structure of any of the switches other than the at least one switch; or heat resistance of the at least one switch is higher than heat resistance of any of the switches other than the at least one switch.

These general and specific aspects may be implemented using a system, a method, an integrated circuit, a computer program, or a computer-readable recording medium such as a CD-ROM, or any combination of systems, methods, integrated circuits, computer programs, or computer-readable recording media.

### Advantageous Effects of Invention

The DC-DC converter and others according to an aspect of the present disclosure are capable of achieving compliance with the operating conditions that require a large output current when an output voltage is low, while reducing costs.

### BRIEF DESCRIPTION OF DRAWINGS

FIG. 1 is a circuit configuration diagram showing an example of a DC-DC converter according to an embodiment.

FIG. 2 is a diagram showing Example 1 of the control of switches according to the embodiment.

FIG. 3 is a diagram showing the gate voltages of the switches, the drain current and the drain-source voltage of a first switch, and the drain current and the drain-source voltage of a second switch in Example 1.

FIG. 4 is a diagram for describing the effects achieved by the present disclosure.

FIG. 5 is a diagram showing Example 2 of the control of the switches according to the embodiment.

FIG. 6 is a diagram showing Example 3 of the control of the switches according to the embodiment.

FIG. 7 is a diagram showing Example 4 of the control of the switches according to the embodiment.

FIG. 8 is a flowchart showing an example of the control method according to other embodiments.

### DESCRIPTION OF EMBODIMENT

Hereinafter, a certain exemplary embodiment is described in greater detail with reference to the accompanying Drawings.

Note that the embodiment described below shows a comprehensive or specific example. The numerical values, shapes, materials, elements, the arrangement and connection of the elements, the steps, the processing order of the steps shown in the following embodiment are examples and not intended to limit the present disclosure.

### Embodiment

The following describes the DC-DC converter according to an embodiment.

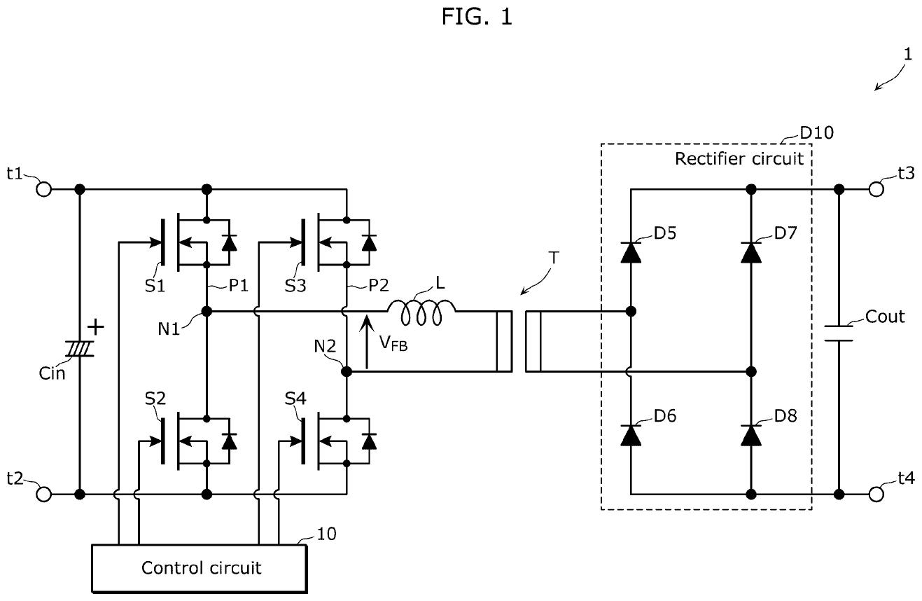

FIG. 1 is a circuit configuration diagram showing an example of DC-DC converter 1 according to the embodiment. FIG. 1 also shows capacitors Cin and Cout in addition to DC-DC converter 1. Capacitors Cin and Cout may be included in DC-DC converter 1.

DC-DC converter 1 is a DC-DC converter of an isolated type that boosts or steps down an input voltage to a predetermined voltage and outputs the resulting voltage. DC-DC converter 1 includes terminals t1, t2, t3, and t4. Terminal t1 is an input terminal. Terminal t2 is a first ground terminal. Terminal t3 is an output terminal. Terminal t4 is a second ground terminal. Note that since DC-DC converter 1 is a DC-DC converter of an isolated type, terminal t1 and terminal t2 are electrically isolated from terminal t3 and terminal t4.

Capacitor Cin is an input capacitor connected between terminal t1 and terminal t2, and capacitor Cout is an output capacitor (smoothing capacitor) connected between terminal t3 and terminal t4.

DC-DC converter 1 includes switches S1, S2, S3, and S4, inductor L, transformer T, rectifier circuit D10, and control circuit 10.

Switch S1 is an example of the first switch that is provided on path P1 connecting terminal t1 and terminal t2. Path P1 is an example of the first path. Switch S2 is an example of the second switch that is provided on path P1 and connected in series with switch S1.

Switch S3 is an example of the third switch that is provided on path P2 different from path P1 and connecting terminal t1 and terminal t2. Path P2 is an example of the second path. Switch S4 is an example of the fourth switch that is provided on path P2 and connected in series with switch S3.

The types and specifications of switches S1, S2, S3, and S4 are determined at design time of DC-DC converter 1, for example, in accordance with how the switching (on and off) of switches S1, S2, S3, and S4 is controlled. In the present disclosure, DC-DC converter 1 is designed to satisfy one of the following: the on-resistance of at least one switch among switches S1, S2, S3, and S4 is lower than the on-resistance of any of the switches other than the at least one switch; the cooling performance of the cooling structure of the at least one switch is higher than the cooling performance of the cooling structure of any of the switches other than the at least one switch; or the heat resistance of the at least one switch is higher than the heat resistance of any of the switches other than the at least one switch.

The following describes an example in which the at least one switch is a Metal Oxide Semiconductor Field Effect Transistor (MOSFET) with low on-resistance, and the switches other than the at least one switch are MOSFETs with high on-resistance. In general, MOSFETs with low on-resistance are transistors that are higher in specification and price than MOSFETs with high on-resistance.

For example, in the example described here (Example 1), the at least one switch is two switches among switches S1, S2, S3, and S4, and these two switches are a combination of switches S1 and S3, or a combination of switches S2 and S4. For example, the two switches are switches S2 and S4, and the switches other than the two switches are switches S1 and S3.

Switch S1 is, for example, an N-channel MOSFET with high on-resistance. The drain of switch S1 is connected to terminal t1, and the source of switch S1 is connected to the drain of switch S2. FIG. 1 also shows a parasitic diode of switch S1. In the equivalent circuit, the anode of such diode is connected to the source of switch S1 and the cathode of such diode is connected to the drain of switch S1.

Switch S2 is, for example, an N-channel MOSFET with low on-resistance. The drain of switch S2 is connected to the source of switch S1 and the source of switch S2 is connected to terminal t2. FIG. 1 also shows a parasitic diode of switch S2. In the equivalent circuit, the anode of such diode is connected to the source of switch S2 and the cathode of such diode is connected to the drain of switch S2.

Switch S3 is, for example, an N-channel MOSFET with high on-resistance. The drain of switch S3 is connected to terminal t1 and the source of switch S3 is connected to the drain of switch S4. FIG. 1 also shows a parasitic diode of switch S3. In the equivalent circuit, the anode of such diode is connected to the source of switch S3 and the cathode of such diode is connected to the drain of switch S3.

Switch S4 is, for example, an N-channel MOSFET with low on-resistance. The drain of switch S4 is connected to the source of switch S3 and the source of switch S4 is connected to terminal 2. FIG. 1 also shows a parasitic diode of switch S4. In the equivalent circuit, the anode of such diode is connected to the source of switch S4 and the cathode of such diode is connected to the drain of switch S4.

Transformer T, which is a transformer of an isolated type, includes a primary winding and a secondary winding that are isolated from each other. The primary winding is connected between node N1 that is located between switch S1 and switch S2 on path P1 and node N2 that is located between switch S3 and switch S4 on path P2. Node N1 is an example of the first node and node N2 is an example of the second node. Both ends of the secondary winding are connected to rectifier circuit D10.

In the example shown in FIG. 1, inductor L is connected between node N1 and the primary winding, and the primary winding is connected between inductor L and node N2. Note that inductor L may be connected between the secondary winding of transformer T and rectifier circuit D10. Inductor L may also be a leakage inductance of transformer T. In addition to the inductor provided between the primary winding of transformer T and node N1 or between the secondary winding of transformer T and rectifier circuit D10, an inductor may also be provided between terminal t3 and rectifier circuit D10.

Rectifier circuit D10 is connected to the secondary winding of transformer T. Rectifier circuit D10 is a full-bridge circuit that is configured using diodes D5, D6, D7, and D8, and thus capable of full-wave rectification. One end of the secondary winding is connected to the anode of diode D5 and the cathode of diode D6, and the other end of the secondary winding is connected to the anode of diode D7 and the cathode of diode D8. Note that rectifier circuit D10 may also be a full-bridge circuit that is configured using four switches (e.g., MOSFETS).

Control circuit 10 is a circuit for controlling the switching (on and off) of the switches included in DC-DC converter 1 (e.g., switches S1, S2, S3, and S4). Control circuit 10 controls the switching of switches S1, S2, S3, and S4 by, for example, controlling a gate drive circuit (not shown) connected to the gates of switches S1, S2, S3, and S4 via, for example, a Pulse Width Modulation (PWM) generator (not shown).

Control circuit 10 is, for example, a computer including, for example, a processor (microprocessor), a memory, etc. The memory is, for example, a Read Only Memory (ROM) and a Random Access Memory (RAM), and is capable of storing a program executed by the processor.

Control circuit 10 controls the switching of switches S1, S2, S3, and S4 to cause the effective value of a current flowing through at least one switch among switches S1, S2, S3, and S4 to be larger than the effective value of a current flowing through any of the switches other than the at least one switch. Since control circuit 10 is designed to control the switching of switches S1, S2, S3, and S4 in such manner, the at least one switch is designed to have lower on-resistance than the on-resistance of any of the switches other than the at least one switch.

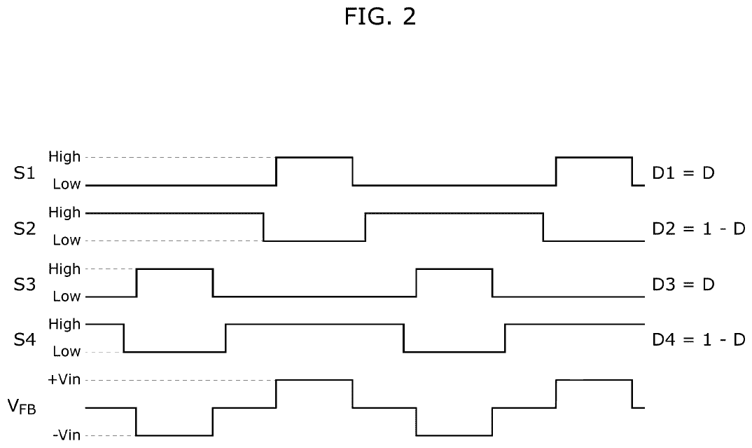

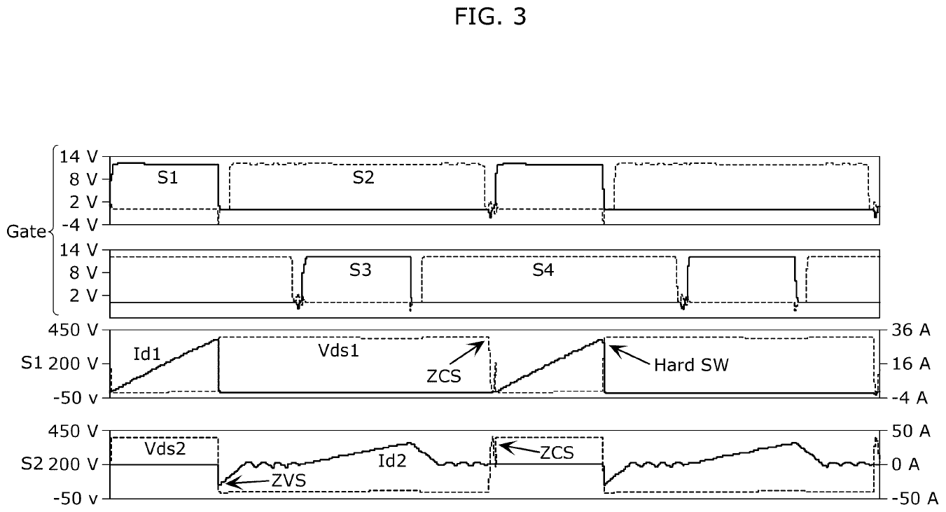

With reference to FIG. 2 and FIG. 3, the following describes the details of the control of the switching of switches S1, S2, S3, and S4 performed by control circuit 10.

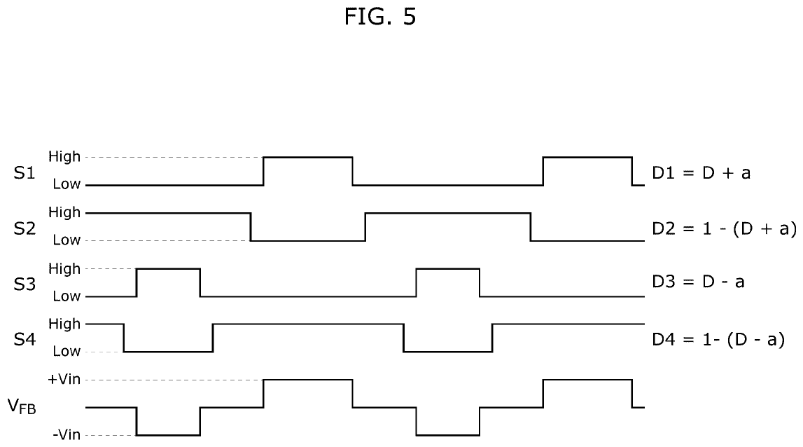

FIG. 2 is a diagram showing Example 1 of the control of switches S1, S2, S3, and S4 according to the embodiment. FIG. 2 shows timing charts of gate voltages of switches S1, S2, S3, and S4, and voltage V_{FB} generated in the primary winding of transformer T. Each of switches S1, S2, S3, and S4 turns on when the gate voltage is High and turns off when the gate voltage is Low. Voltage V_{FB} is generated when one end of the primary winding of transformer T is in conduction with one of terminals t1 or t2, and the other end of the primary winding of transformer T is in conduction with the other of terminals t1 or t2. More specifically, when switches S1 and S4 are on and switches S2 and S3 are off, +Vin is generated as voltage V_{FB}, and when switches S1 and S4 are off and switches S2 and S3 are on, −Vin is generated as voltage V_{FB}. The same applies to FIG. 5 to FIG. 7 described below.

Control circuit 10 adjusts duty ratios D1, D2, D3, and D4 of switches S1, S2, S3, and S4 to bring the output voltage of DC-DC converter 1 to a desired voltage (i.e., performs duty control). Alternatively, control circuit 10 adjusts the phase difference between the switching phase of switches S1 and S2 and the switching phase of switches S3 and S4 (i.e., performs phase-shift control).

FIG. 3 is a diagram showing the gate voltages of switches S1, S2, S3, and S4, the collector current and the drain-source voltage of switch S1, and the drain current and the drain-source voltage of switch S2 in Example 1. The drain current and the drain-source voltage of switch S3 are basically the same as those of switch S1, except that their phases are different, and thus the illustration is omitted. Also, the drain current and the drain-source voltage of switch S4 are basically the same as those of switch S2, except that their phases are different, and thus the illustration is omitted.

For example, control circuit 10 controls the switching of switches S1, S2, S3, and S4 to cause the duty ratio for the switching of the at least one switch to be larger than the duty ratio for the switching of any of the switches other than the at least one switch, thereby causing the effective value of a current flowing through the at least one switch to be larger than the effective value of a current flowing through any of the switches other than the at least one switch. In Example 1, since the at least one switch is switches S2 and S4, control circuit 10 controls the switching of switches S1, S2, S3, and S4 to cause the duty ratio for the switching of switches S2 and S4 to be larger than the duty ratio for the switching of switches S1 and S3. It can be seen from FIG. 2 and FIG. 3 that the duty ratio for the switching of switches S2 and S4 is larger than the duty ratio for the switching of switches S1 and S3. With this, as shown in FIG. 3, it is possible to cause the effective value of the current (drain current) flowing through switch S2 to be larger than the effective value of the current (drain current) flowing through switch S1. Although not shown, it is also possible to cause the effective value of the current flowing through switch S4 to be larger than the effective value of the current flowing through switch S3 in the same manner.

There is an increasing need for downsizing of DC-DC converters. In particular, downsizing of passive components such as inductors and capacitors that constitute a major part of the size of DC-DC converters is increasingly required. In the downsizing of passive components, the use of the same drive frequency (switching frequency) as the one used before the downsizing results in an increase in current ripple. As such, it is necessary to drive a DC-DC converter at high frequency. On the other hand, since high-frequency drive causes a switching loss every time switching is performed, it is necessary to perform soft switching. For this reason, as shown in FIG. 3, DC-DC converter 1 performs soft switching by performing so-called Zero Current Switching (ZCS), which is performed with the current flowing through switch S1 at zero, and so-called Zero Volt Switching (ZVS), which is performed with the voltage applied to switch S2 at zero. With this, it is possible to reduce switching losses.

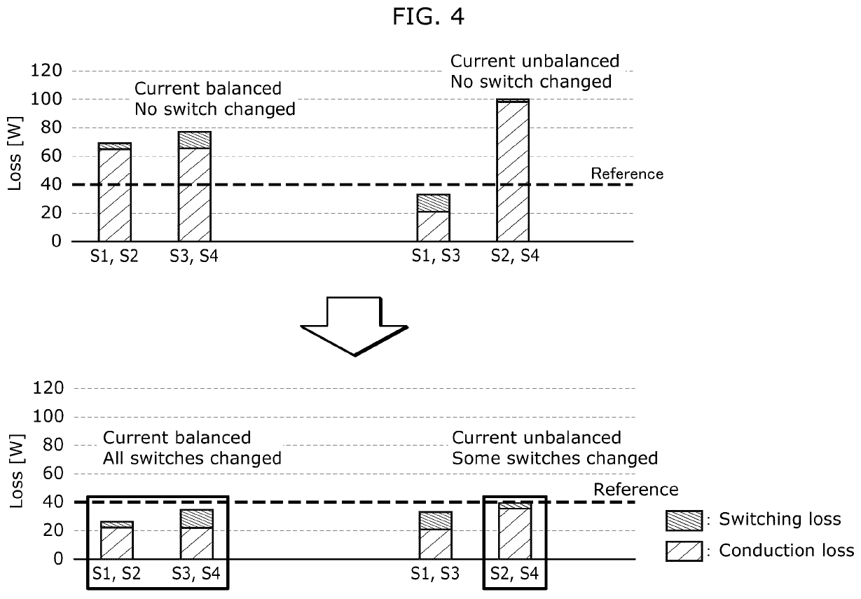

With reference to FIG. 4, the following describes the effects achieved by setting lower on-resistance to a switch in which the effective value of a current flowing therethrough is large than the on-resistance of any of the switches other than such switch.

FIG. 4 is a diagram for describing the effects achieved by the present disclosure. FIG. 4 shows the losses (more specifically, switching loss and conduction loss) generated in switches S1, S2, S3, and S4 when a large current is passed through the primary side of DC-DC converter 1 to achieve compliance with the operating conditions that require a large output current when an output voltage is low. In FIG. 4, the reference of the allowable loss is set, for example, at 40 W.

The upper left of FIG. 4 shows the losses generated in switches S1, S2, S3, and S4 in the case where all switches S1, S2, S3, and S4 are MOSFETs with high on-resistance and phase-shift control is performed using the same duty ratio (e.g., 50%) for the switching of all switches S1, S2, S3, and S4 (stated differently, the case where the effective values of currents flowing through switches S1, S2, S3, and S4 are balanced).

The upper right of FIG. 4 shows the losses generated in switches S1, S2, S3, and S4 in the case where all switches S1, S2, S3, and S4 are MOSFETs with high on-resistance and duty control is performed to cause the duty ratio for the switching of switches S2 and S4 to be larger than the duty ratio for the switching of switches S1 and S3 (stated differently, the case where the effective values of currents flowing through switches S1, S2, S3, and S4 are unbalanced).

The lower left of FIG. 4 shows the losses generated in switches S1, S2, S3, and S4 in the case where all switches S1, S2, S3, and S4 are MOSFETs with low on-resistance and phase-shift control is performed using the same duty ratio (e.g., 50%) for the switching of all switches S1, S2, S3, and S4 (stated differently, the case where the effective values of currents flowing through switches S1, S2, S3, and S4 are balanced).

The lower right of FIG. 4 shows the losses generated in switches S1, S2, S3, and S4 in the case where switches S2 and S4 are MOSFETS with low on-resistance and switches S1 and S3 are MOSFETs with high on-resistance, and duty control is performed to cause the duty ratio for the switching of switches S2 and S4 to be larger than the duty ratio for the switching of switches S1 and S3 (stated differently, the case where the effective values of currents flowing through switches S1, S2, S3, and S4 are unbalanced).

As shown in the upper left of FIG. 4, when the duty ratios for the switching of switches S1, S2, S3, and S4 are the same and all switches S1, S2, S3, and S4 are MOSFETs with high on-resistance, the effective values of the currents flowing through switches S1, S2, S3, and S4 are uniformly large. Also, since the on-resistance of switches S1, S2, S3, and S4 is high, all the losses generated in switches S1, S2, S3, and S4 exceed the reference when a large current is passed through the primary side.

As shown in the upper right of FIG. 4, when the duty ratio for the switching of switches S2 and S4 is set to be larger than the duty ratio for the switching of switches S1 and S3 and all switches S1, S2, S3, and S4 are MOSFETs with high on-resistance, the on-resistance of switches S1 and S3 is high, but the effective values of the currents flowing through switches S1 and S3 are small. For this reason, the losses generated in switches S1 and S3 when a large current is passed through the primary side do not exceed the reference. However, the effective values of the currents flowing through switches S1 and S3 are smaller, as a result of which the effective values of the currents flowing through switches S2 and S4 are larger. Additionally, since the on-resistance of switches S2 and S4 is high, the losses generated in switches S2 and S4 when a large current is passed through the primary side are significantly large, exceeding the reference.

As shown in the lower left of FIG. 4, when the duty ratios for the switching of switches S1, S2, S3, and S4 are the same and all switches S1, S2, S3, and S4 are MOSFETs with low on-resistance, the effective values of the currents flowing through switches S1, S2, S3, and S4 are uniformly large. However, since the on-resistance of switches S1, S2, S3, and S4 is low, none of the losses generated in switches S1, S2, S3, and S4 exceeds the reference when a large current is passed through the primary side.

As shown in the lower right of FIG. 4, when the duty ratio for the switching of switches S2 and S4 is set to be larger than the duty ratio for the switching of switches S1 and S3, and switches S1 and S3 are MOSFETs with high on-resistance and switches S2 and S4 are MOSFETs with low on-resistance, the on-resistance of switches S1 and S3 is high, but the effective values of the currents flowing through switches S1 and S3 are small. For this reason, the losses generated in switches S1 and S3 when a large current is passed through the primary side do not exceed the reference. Also, the effective values of the currents flowing through switches S1 and S3 are smaller, as a result of which the effective values of the currents flowing through switches S2 and S4 are larger. However, since the on-resistance of switches S2 and S4 is low, the losses generated in switches S2 and S4 when a large current is passed through the primary side do not exceed the reference. In this case, therefore, by simply using MOSFETs with low on-resistance as switches S2 and S4 without using MOSFETs with low on-resistance as switches S1 and S3, it is possible to cause none of the losses generated in switches S1, S2, S3, and S4 to exceed the reference when a large current is passed through the primary side.

Note that, as shown in FIG. 5, the value of the duty ratio for the switching of switch S1 may be different from the value of the duty ratio for the switching of switch S3, and the value of the duty ratio for the switching of switch S2 may be different from the value of the duty ratio for the switching of switch S4.

FIG. 5 is a diagram showing Example 2 of the control of switches S1, S2, S3, and S4 according to the embodiment.

Example 1 assumes, as shown in FIG. 2, that duty ratios D1 and D3 for the switching of switches S1 and S3 are D, and that duty ratios D2 and D4 for the switching of switches S2 and S4 are 1-D. For example, as shown in FIG. 5, duty ratio D1 for the switching of switch S1 may be D+a, duty ratio of D2 for the switching of switch S2 may be 1−(D+a), duty ratio D3 for the switching of switch S3 may be D−a, and duty ratio D4 for the switching of switch S4 may be 1−(D−a).

In Example 2, it is possible to: cause the effective value of a current flowing through switch S4 to be larger than the effective value of a current flowing through switch S2; cause the effective value of a current flowing through switch S2 to be larger than the effective value of a current flowing through switch S1; and cause the effective value of a current flowing through switch S1 to be larger than the effective value of a current flowing through switch S3.

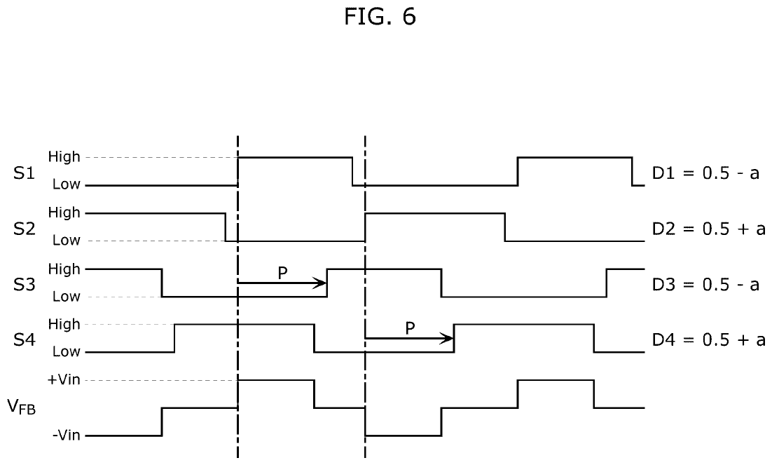

Note that Example 1 and Example 2 are examples in which the phase difference between the switching phase of switches S1 and S2 and the switching phase of switches S3 and S4 is fixed, and the output voltage is adjusted by adjusting duty ratios D1, D2, D3, and D4. Instead of this, duty ratios D1, D2, D3 and D4 may be fixed, and the phase difference between the switching phase of switches S1 and S2 and the switching phase of switches S3 and S4 may be adjusted. This will be described with reference to FIG. 6.

FIG. 6 is a diagram showing Example 3 of the control of switches S1, S2, S3, and S4 according to the embodiment.

For example, as shown in FIG. 6, duty ratio D1 for the switching of switch S1 may be 0.5-a, duty ratio D2 for the switching of switch S2 may be 0.5+a, duty ratio D3 for the switching of switch S3 may be 0.5-a, and duty ratio D4 for the switching of switch S4 may be 0.5+a.

In Example 3, as in Example 1, it is possible to cause the effective values of currents flowing through switches S2 and S4 to be larger than the effective values of currents flowing through switches S1 and S3. In Example 3, it is also possible to adjust the period during which voltage V_{FB} is generated in the primary winding of transformer T and to adjust the output voltage using duty ratios D1, D2, D3, and D4 that are fixed and adjusting phase difference P between the switching phase of switches S1 and S2 and the switching phase of switches S3 and S4.

Note that in Example 1, Example 2, and Example 3, a combination of the two switches in which the effective values of currents flowing therethrough are large is a combination of switches S1 and S3, but a combination of the two switches in which the effective values of currents flowing therethrough are large may also be a combination of switches S2 and S4.

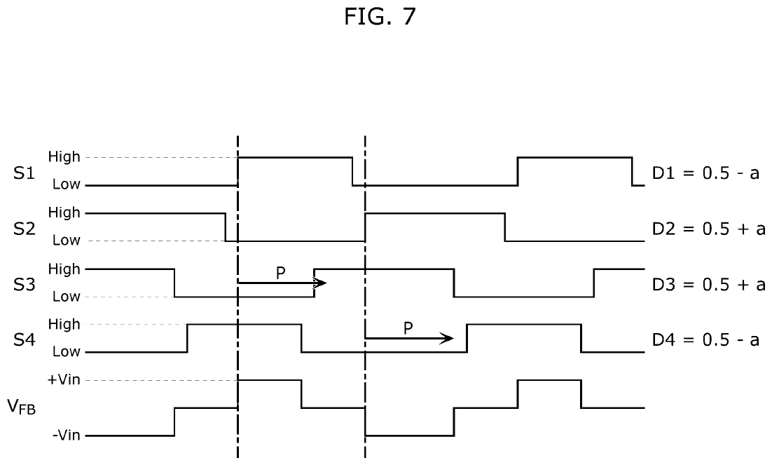

A combination of the two switches in which the effective values of currents flowing therethrough are large may also be a combination of switch S1 and switch S4 or a combination of switch S2 and switch S3. This will be described with reference to FIG. 7.

FIG. 7 is a diagram showing Example 4 of the control of switches S1, S2, S3, and S4 according to the embodiment.

In Example 4, a combination of the two switches in which the effective values of currents flowing therethrough are large is a combination of switches S2 and S3. As shown in FIG. 7, duty ratio D1 for the switching of switch S1 may be 0.5-a, duty ratio D2 for the switching of switch S2 may be 0.5+a, duty ratio D3 for the switching of switch S3 may be 0.5+a, and duty ratio D4 for the switching of switch S4 may be 0.5-a.

In Example 4, it is possible to cause the effective values of currents flowing through switches S2 and S3 to be larger than the effective values of currents flowing through switches S1 and S4. In Example 4, it is also possible to adjust the period during which voltage V_{FB} is generated in the primary winding of transformer T and to adjust the output voltage using duty ratios D1, D2, D3, and D4 that are fixed and adjusting phase difference P between the switching phase of switches S1 and S2 and the switching phase of switches S3 and S4.

Note that in Example 4, a combination of the two switches in which the effective values of currents flowing therethrough are large is a combination of switches S2 and S3, but a combination of the two switches in which the effective values of currents flowing therethrough are large may also be a combination of switches S1 and S4.

In addition, in Example 1, Example 2, Example 3, and Example 4, the at least one switch in which the effective value of a current flowing therethrough is large is two switches, but the at least one switch in which the effective value of a current flowing therethrough is large may also be a single switch. Stated differently, control circuit 10 may control the switching of switches S1, S2, S3, and S4 to cause the effective value of a current flowing through one switch among switches S1, S2, S3, and S4 to be larger than the effective value of a current flowing through any of the switches other than such one switch.

As described above, by concentrating the current on at least one switch among S1, S2, S3, and S4 to cause DC-DC converter 1 to achieve compliance with the operating conditions that require a large output current when an output voltage is low, instead of setting the effective values of currents flowing through these switches not to be uniform, it is possible to cause the effective values of currents flowing through the switches other than the at least one switch to be small. With this, it is possible use low-specification switches with high on-resistance as the switches other than the at least one switch, and use a high-specification switch with low on-resistance only as the at least one switch in which the effective value of a current flowing therethrough is large. This achieves compliance with the operating conditions that require a large output current when an output voltage is low, while reducing costs.

Note that the at least one switch in which the effective value of a current flowing therethrough is large may have a cooling structure with high cooling performance, and the switches other than the at least one switch may have a cooling structure with low cooling performance. In general, more expensive components are used for the cooling structure with high cooling performance than those used for the cooling structure with low cooling performance. In this case, too, it is possible to use switches having a low-cost cooling structure with low cooling performance as the switches other than the at least one switch, and use a switch having a high-cost cooling structure with high cooling performance only as the at least one switch in which the effective value of a current flowing therethrough is large. This achieves compliance with the operating conditions that require a large output current when an output voltage is low, while reducing costs.

In addition, the at least one switch in which the effective value of a current flowing therethrough is large may also be a switch with high heat resistance, and the switches other than the at least one switch may be switches with low heat resistance. The switch with high heat resistance is a switch in which rated temperature Tj of a junction is high, such as a SiC MOSFET. The maximum value of rated temperature Tj of a conventional Si MOSFET is 150° C., while the maximum value of rated temperature Tj of a SIC MOSFET is 175° C. Also, since rated temperature Tj of some Isolated Gate Bipolar Transistors (IGBTs) is 175° C., the switch with high heat resistance may be an IGBT. In this case, too, it is possible to use low-specification switches with low heat resistance as the switches other than the at least one switch, and use a high-specification switch with high heat resistance only as the at least one switch in which the effective value of a current flowing therethrough is large. This achieves compliance with the operating conditions that require a large output current when an output voltage is low, while reducing costs.

By setting a large duty ratio to the at least one switch, it is possible to cause the effective value of a current flowing through the at least one switch to be large. Stated differently, by setting a small duty ratio to the switches other than the at least one switch, it is possible to cause the effective values of currents flowing through the switches other than the at least one switch to be small.

For example, as in Example 1 to Example 4, by concentrating the current only on two switches among switches S1, S2, S3, and S4, it is possible to cause the effective values of currents flowing through the other two switches to be small. This enables the use of low-specification switches with high on-resistance as the other two switches, thereby reducing costs.

For example, as in Example 1 to Example 3, by concentrating the current only on one of the combination of switches S1 and S3 or the combination of switches S2 and S4, it is possible to cause the effective values of currents flowing through the other combination of switches to be small. This enables the use of low-specification switches with high on-resistance as the other combination of switches, thereby reducing costs. Further, by concentrating the current only on one of the combination of switches S1 and S3 or the combination of switches S2 and S4, it is possible to increase the range of variable voltage and the range of soft switching.

### OTHER EMBODIMENTS

The embodiment has been described above to show an example of the technique according to the present disclosure. The technique according to the present disclosure, however, is not limited to this, and thus is applicable to an embodiment obtained by making modification, replacement, addition, omission, etc. to the technique according to the present disclosure. For example, a variation as described below is also included in an embodiment of the present disclosure.

For example, the present disclosure can be realized not only in the form of DC-DC converter 1, but also in the form of a control method that includes steps (processes) performed by the elements included in DC-DC converter 1.

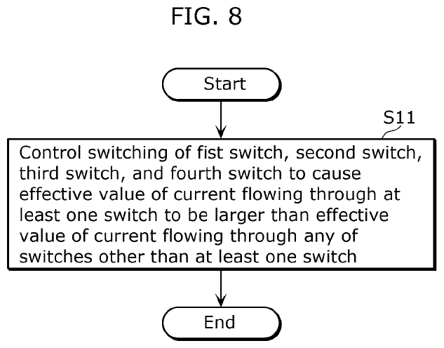

FIG. 8 is a flowchart showing an example of the control method according to other embodiments.

The control method is a control method executed by DC-DC converter 1 of an isolated type, including: a first switch that is provided on a first path connecting an input terminal and a ground terminal; a second switch that is provided on the first path and connected in series with the first switch; a third switch that is provided on a second path connecting the input terminal and the ground terminal, the second path being different from the first path; a fourth switch that is provided on the second path and connected in series with the third switch; a transformer that includes a primary winding connected between a first node and a second node, the first node being located between the first switch and the second switch on the first path, the second node being located between the third switch and the fourth switch on the second path; and a rectifier circuit that is connected to a secondary winding of the transformer. In the control method, as shown in FIG. 8, switching of the first switch, the second switch, the third switch, and the fourth switch is controlled to cause an effective value of a current flowing through at least one switch among switches to be larger than an effective value of a current flowing through any of the switches other than the at least one switch, the switches being the first switch, the second switch, the third switch, and the fourth switch (step S11), and one of the following is satisfied: on-resistance of the at least one switch is lower than on-resistance of any of the switches other than the at least one switch; cooling performance of a cooling structure of the at least one switch is higher than cooling performance of a cooling structure of any of the switches other than the at least one switch; or heat resistance of the at least one switch is higher than heat resistance of any of the switches other than the at least one switch.

The present disclosure can be realized, for example, in the form of a program for causing a computer (processor) to execute the steps included in the control method. Further, the present disclosure can be realized in the form of a non-transitory, computer-readable recording medium such as a CD-ROM having recorded thereon such program.

When the present disclosure is realized in the form of a program (software), the steps are executed by means of the program being executed using hardware resources of the computer, such as a CPU, a memory, and an input-output circuit. Stated differently, the steps are executed by mans of the CPU obtaining data from, for example, the memory or the input-output circuit to perform calculations, and outputting calculation results to, for example, the memory or the input-output circuit.

Each of the elements included in DC-DC converter 1 in the foregoing embodiment may be configured in the form of an exclusive hardware product, or may be realized by executing a software program suitable for the element. Each of the elements may be realized by means of a program executing unit, such as a CPU and a processor, reading and executing the software program recorded on a recording medium such as a hard disk or a semiconductor memory.

Note that the functions of DC-DC converter 1 according to the foregoing embodiment may be realized, in part or in whole, in the form of a large-scale integration (LSI), which is typically an integrated circuit. These may take the form of individual chips, or may be encapsulated into a single chip in part or in whole. Also, the circuit integration is not limited to the integration into an LSI, and thus may be realized in the form of an exclusive circuit or a general-purpose processor. A field programmable gate array (FPGA) that allows for programming after the manufacture of an LSI, or a reconfigurable processor that allows for reconfiguration of the connection and the settings of circuit cells inside an LSI may be employed.

Furthermore, when a circuit integration technique that replaces LSIs becomes available as a result of the future progress in the semiconductor technique or other derivative techniques, such technique may certainly be employed to integrate the elements included in DC-DC converter 1 into an integrated circuit.

The scope of the present disclosure also includes an embodiment achieved by making various modifications to the embodiment that can be conceived by those skilled in the art and an embodiment achieved by freely combining elements and functions in each embodiment without departing from the essence of the present

### (Added Notes)

From the above description of the embodiment, the following techniques are disclosed.

(Technique 1) A DC-DC converter of an isolated type, the DC-DC converter including: a first switch that is provided on a first path connecting an input terminal and a ground terminal; a second switch that is provided on the first path and connected in series with the first switch; a third switch that is provided on a second path connecting the input terminal and the ground terminal, the second path being different from the first path; a fourth switch that is provided on the second path and connected in series with the third switch; a transformer that includes a primary winding connected between a first node and a second node, the first node being located between the first switch and the second switch on the first path, the second node being located between the third switch and the fourth switch on the second path; a rectifier circuit that is connected to a secondary winding of the transformer; and a control circuit that controls switching of the first switch, the second switch, the third switch, and the fourth switch to cause an effective value of a current flowing through at least one switch among switches to be larger than an effective value of a current flowing through any of the switches other than the at least one switch, the switches being the first switch, the second switch, the third switch, and the fourth switch, wherein one of the following is satisfied: on-resistance of the at least one switch is lower than on-resistance of any of the switches other than the at least one switch; cooling performance of a cooling structure of the at least one switch is higher than cooling performance of a cooling structure of any of the switches other than the at least one switch; or heat resistance of the at least one switch is higher than heat resistance of any of the switches other than the at least one switch.

With this, by concentrating the current on at least one switch among the first switch, the second switch, the third switch, and the fourth switch to cause the DC-DC converter to achieve compliance with the operating conditions that require a large output current when an output voltage is low, instead of setting the effective values of currents flowing through these switches not to be uniform, it is possible to cause the effective values of currents flowing through the switches other than the at least one switch to be small. For this reason, it is possible use low-specification switches with high on-resistance as the switches other than the at least one switch, and use a high-specification switch with low on-resistance only as the at least one switch in which the effective value of a current flowing therethrough is large. Alternatively, it is possible to use switches having a low-cost cooling structure with low cooling performance as the switches other than the at least one switch, and use a switch having a high-cost cooling structure with high cooling performance only as the at least one switch in which the effective value of a current flowing therethrough is large. It is also possible to use low-specification switches with low heat resistance as the switches other than the at least one switch, and use a high-specification switch with high heat resistance only as the at least one switch in which the effective value of a current flowing therethrough is large. This achieves compliance with the operating conditions that require a large output current when an output voltage is low, while reducing costs.

(Technique 2) The DC-DC converter according to Technique 1, wherein the control circuit causes the effective value of the current flowing through the at least one switch to be larger than the effective value of the current flowing through any of the switches other than the at least one switch by controlling the switching of the first switch, the second switch, the third switch, and the fourth switch to cause a duty ratio for switching of the at least one switch to be larger than a duty ratio for switching of any of the switches other than the at least one switch.

With this, by setting a large duty ratio to the at least one switch, it is possible to cause the effective value of a current flowing through the at least one switch to be large. Stated differently, by setting a small duty ratio to the switches other than the at least one switch, it is possible to cause the effective values of currents flowing through the switches other than the at least one switch to be small.

(Technique 3) The DC-DC converter according to Technique 1 or 2, wherein the at least one switch is two switches among the first switch, the second switch, the third switch, and the fourth switch.

With this, by concentrating the current only on two switches among the first switch, the second switch, the third switch, and the fourth switch, it is possible to cause the effective values of currents flowing through the other two switches to be small. This enables the use of low-specification switches with high on-resistance as the other two switches, thereby reducing costs.

(Technique 4) The DC-DC converter according to Technique 3, wherein the two switches are a combination of the first switch and the third switch or a combination of the second switch and the fourth switch.

With this, by concentrating the current only on one of the combination of the first switch and the third switch or the combination of the second switch and the fourth switch, it is possible to cause the effective values of currents flowing through the other combination of the switches to be small. This enables the use of low-specification switches with high on-resistance as the other combination of the switches, thereby reducing costs. Further, by concentrating the current only on one of the combination of the first switch and the third switch or the combination of the second switch and the fourth switch, it is possible to increase the range of variable voltage and the range of soft switching range.

(Technique 5) The DC-DC converter according to any one of Techniques 1 to 4, further including: an inductor that is connected between the primary winding and the first node or between the secondary winding and the rectifier circuit.

As described above, the inductor may be connected to the primary winding or the secondary winding of the transformer.

(Technique 6) A control method executed by a DC-DC converter of an isolated type, the DC-DC converter including: a first switch that is provided on a first path connecting an input terminal and a ground terminal; a second switch that is provided on the first path and connected in series with the first switch; a third switch that is provided on a second path connecting the input terminal and the ground terminal, the second path being different from the first path; a fourth switch that is provided on the second path and connected in series with the third switch; a transformer that includes a primary winding connected between a first node and a second node, the first node being located between the first switch and the second switch on the first path, the second node being located between the third switch and the fourth switch on the second path; and a rectifier circuit that is connected to a secondary winding of the transformer, the control method including: controlling switching of the first switch, the second switch, the third switch, and the fourth switch to cause an effective value of a current flowing through at least one switch among switches to be larger than an effective value of a current flowing through any of the switches other than the at least one switch, the switches being the first switch, the second switch, the third switch, and the fourth switch, wherein one of the following is satisfied: on-resistance of the at least one switch is lower than on-resistance of any of the switches other than the at least one switch; cooling performance of a cooling structure of the at least one switch is higher than cooling performance of a cooling structure of any of the switches other than the at least one switch; or heat resistance of the at least one switch is higher than heat resistance of any of the switches other than the at least one switch.

With this, it is possible to provide a control method capable of achieving compliance with the operating conditions that require a large output current when an output voltage is low, while reducing costs.

### INDUSTRIAL APPLICABILITY

The present disclosure is applicable for use, for example, as DC-DC converters of an isolated type.

### REFERENCE SIGNS LIST

1 DC-DC converter
10 control circuit
Cin, Cout capacitor
D5, D6, D7, D8 diode
D10 rectifier circuit
L inductor
N1, N2 node
P1, P2 path
S1, S2, S3, S4 switch
T transformer
t1, t2, t3, t4 terminal

1. A DC-DC converter of an isolated type, the DC-DC converter comprising:
a first switch that is provided on a first path connecting an input terminal and a ground terminal;
a second switch that is provided on the first path and connected in series with the first switch;
a third switch that is provided on a second path connecting the input terminal and the ground terminal, the second path being different from the first path;
a fourth switch that is provided on the second path and connected in series with the third switch;
a transformer that includes a primary winding connected between a first node and a second node, the first node being located between the first switch and the second switch on the first path, the second node being located between the third switch and the fourth switch on the second path;
a rectifier circuit that is connected to a secondary winding of the transformer; and
a control circuit that controls switching of the first switch, the second switch, the third switch, and the fourth switch to cause an effective value of a current flowing through at least one switch among switches to be larger than an effective value of a current flowing through any of the switches other than the at least one switch, the switches being the first switch, the second switch, the third switch, and the fourth switch,
wherein one of the following is satisfied:
on-resistance of the at least one switch is lower than on-resistance of any of the switches other than the at least one switch;
cooling performance of a cooling structure of the at least one switch is higher than cooling performance of a cooling structure of any of the switches other than the at least one switch; or
heat resistance of the at least one switch is higher than heat resistance of any of the switches other than the at least one switch.

2. The DC-DC converter according to claim 1,
wherein the control circuit causes the effective value of the current flowing through the at least one switch to be larger than the effective value of the current flowing through any of the switches other than the at least one switch by controlling switching of the first switch, the second switch, the third switch, and the fourth switch to cause a duty ratio for switching of the at least one switch to be larger than a duty ratio for switching of any of the switches other than the at least one switch.

3. The DC-DC converter according to claim 1,
wherein the at least one switch is two switches among the first switch, the second switch, the third switch, and the fourth switch.

4. The DC-DC converter according to claim 3,
wherein the two switches are a combination of the first switch and the third switch or a combination of the second switch and the fourth switch.

5. The DC-DC converter according to claim 1, further comprising:
an inductor that is connected between the primary winding and the first node or between the secondary winding and the rectifier circuit.

6. A control method executed by a DC-DC converter of an isolated type, the DC-DC converter including:
a first switch that is provided on a first path connecting an input terminal and a ground terminal;
a second switch that is provided on the first path and connected in series with the first switch;
a third switch that is provided on a second path connecting the input terminal and the ground terminal, the second path being different from the first path;
a fourth switch that is provided on the second path and connected in series with the third switch;
a transformer that includes a primary winding connected between a first node and a second node, the first node being located between the first switch and the second switch on the first path, the second node being located between the third switch and the fourth switch on the second path; and
a rectifier circuit that is connected to a secondary winding of the transformer,
the control method comprising:
controlling switching of the first switch, the second switch, the third switch, and the fourth switch to cause an effective value of a current flowing through at least one switch among switches to be larger than an effective value of a current flowing through any of the switches other than the at least one switch, the switches being the first switch, the second switch, the third switch, and the fourth switch,
wherein one of the following is satisfied:
on-resistance of the at least one switch is lower than on-resistance of any of the switches other than the at least one switch;
cooling performance of a cooling structure of the at least one switch is higher than cooling performance of a cooling structure of any of the switches other than the at least one switch; or
heat resistance of the at least one switch is higher than heat resistance of any of the switches other than the at least one switch.
